(19) United States
(12) Patent Application Publication
(10) Pub. No.: US 2012/0175695 A1
(43) Pub. Date: Jul. 12, 2012

(54) SEMICONDUCTOR STORAGE DEVICE AND MANUFACTURING METHOD THEREOF

(75) Inventors: Yuichi SATO, Yokkaichi-shi (JP); Hideto Takekida, Nagoya-shi (JP)

(73) Assignee: Kabushiki Kaisha Toshiba, Tokyo (JP)

(21) Appl. No.: 13/336,398

(22) Filed: Dec. 23, 2011

(30) Foreign Application Priority Data
Jan. 7, 2011 (JP) 2011-002387

(51) Int. Cl. H01L 29/78; H01L 21/283

(52) U.S. Cl. 257/314; 438/591; 438/593; 257/E29.255; 257/E21.159

(57) ABSTRACT

A semiconductor storage device according to an embodiment includes a memory cell comprising a charge accumulate layer above a semiconductor substrate and a control gate above the charge accumulate layer. The charge accumulate layer is capable of accumulating charges therein. The control gate is configured to control an amount of the charges accumulated in the charge accumulate layer. The control gate comprises a lower-layer control gate part of metal or metallic silicide which is processable by etching, and an upper-layer control gate part of a material different from that of the lower-layer control gate part.

### CROSS REFERENCE TO RELATED APPLICATIONS

This application is based upon and claims the benefit of priority from the prior Japanese Patent Application No. 2011-2387, filed on Jan. 7, 2011, the entire contents of which are incorporated herein by reference.

### FIELD

The embodiments of the present invention relate to a semiconductor storage device and a manufacturing method thereof.

### BACKGROUND

As a type of nonvolatile semiconductor storage devices, a NAND flash memory has been known. The NAND flash memory includes a plurality of memory cells each including a floating gate that has charges accumulated therein and a control gate that controls the charge amount in the floating gate.

The control gate also functions as a word line. As word lines in semiconductor devices are becoming thinner, achieving a lower resistance of the word lines has become increasingly important. Therefore, the control gates are sometimes silicided to lower the resistance of the word lines.

To achieve the lower resistance of the word lines, there are cases where the control gates are fully silicided (so-called FUSI), that is, metal is diffused to the bottoms of the control gates. When the FUSI technology is used, the resistance of the word lines can be lowered; however, in this case, a large quantity of metal is diffused into silicon gates and the metal is reacted with silicon. Therefore, the silicon in the control gates is eroded and voids may be generated in the control gates. When there are voids in the control gates, problems such as inadequate writing can happen.

Meanwhile, when the silicidation of the control gates is stopped at the top portions in order to suppress generation of voids, portions located between the top portions of the control gates and the floating gates are not silicided. In this case, the lower portions of the control gates remain as polysilicon having a high resistance, and therefore the resistance of the entire control gates is larger than those of fully-silicided control gates. Therefore, in this case, it is not possible to satisfy the specifications of the resistance of the word lines required for downscaling of the semiconductor storage device.

As described above, conventionally, achieving a lower resistance of control gates and suppressing generation of voids are in a trade-off relationship, and it has been difficult to realize both issues at the same time.

### BRIEF DESCRIPTION OF THE DRAWINGS

FIG. 1 is a plan view showing a configuration of a semiconductor storage device according to a first embodiment;

FIG. 2A is a cross-sectional view along a line A-A in FIG. 1;

FIG. 2B is a cross-sectional view along a line B-B in FIG. 1;

FIGS. 3A to 7B are cross-sectional views of the manufacturing method of a memory according to the first embodiment; and

FIGS. 8A and 8B are cross-sectional views showing a configuration of a semiconductor storage device according to a second embodiment.

### DETAILED DESCRIPTION

A semiconductor storage device according to an embodiment comprises a memory cell comprising a charge accumulate layer above a semiconductor substrate and a control gate above the charge accumulate layer. The charge accumulate layer is capable of accumulating charges therein. The control gate is configured to control an amount of the charges accumulated in the charge accumulate layer. The control gate comprises a lower-layer control gate part of metal or metallic silicide which is processable by etching, and an upper-layer control gate part of a material different from that of the lower-layer control gate part.

Embodiments will now be explained with reference to the accompanying drawings. The present invention is not limited to the embodiments.

### First Embodiment

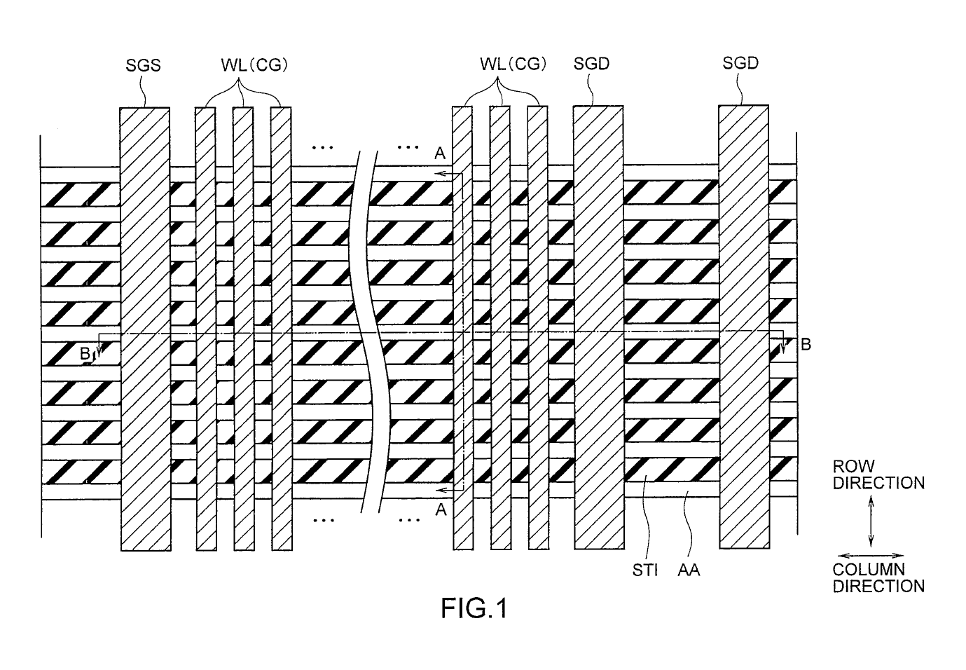

FIG. 1 is a plan view showing a configuration of a semiconductor storage device according to a first embodiment. Although not particularly limited thereto, the semiconductor storage device is a NAND flash memory (hereinafter, also simply “memory”), for example.

The memory according to the first embodiment includes active areas AA and shallow trench isolations STI formed on a semiconductor device. The shallow trench isolations STI are formed in a striped shape so as to extend in a column direction (an extending direction of bit lines). The active areas AA are defined by the shallow trench isolations STI and are formed in a striped shape so as to extend in the column direction similarly to the shallow trench isolations STI. The active areas AA and the shallow trench isolations STI are alternately arranged in a row direction.

Above the active areas AA, floating gates (not shown in FIG. 1) are provided, and control gates CG are provided on upper parts of the floating gates. The control gates CG each function as a word line WL and also function as a gate of a memory cell. The control gates CG extend in a row direction (an extending direction of the word lines) that is substantially orthogonal to the column direction.

Selective gate lines SGD on a drain side and a selective gate line SGS on a source side also extend in the row direction similarly to the control gates CG.

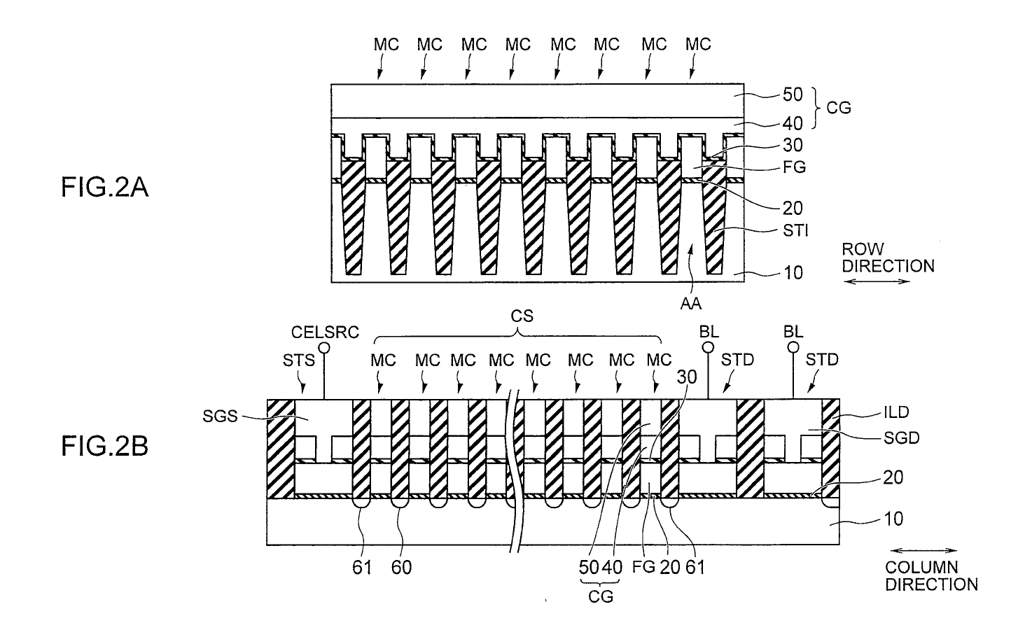

FIG. 2A is a cross-sectional view along a line A-A in FIG. 1. FIG. 2B is a cross-sectional view along a line B-B in FIG. 1. As shown in FIG. 2A, the active areas AA and the shallow trench isolations STI are alternately arranged on a semiconductor substrate (a silicon substrate, for example) 10.

Memory cells MC are formed on the active areas AA. Each of the memory cells MC includes a tunnel dielectric film 20, a floating gate (charge accumulate layer) FG, a gate dielectric film (inter-poly dielectric) 30, the control gate CG, and a diffusion layer (source/drain) 60. The tunnel dielectric film 20 is provided on the semiconductor substrate 10. The floating gate FG is provided on each of the active areas AA of the semiconductor substrate 10 via the tunnel dielectric film 20. The floating gate FG is arranged correspondingly for each of the memory cells MC and stores data therein by accumulating charges or discharging charges via the tunnel dielectric film 20. When the memory cell MC is configured by an N-type FET (Field Effect Transistor), the floating gate FG can store data therein by accumulating electrons or discharging electrons. The gate dielectric film 30 is provided on the floating gate FG.

The control gate CG is provided on the floating gate FG via the gate dielectric film 30 and controls the amount of charges accumulated in the floating gate FG. In the first embodiment, the control gate CG has a double-layer structure including a lower-layer control gate part 40 and an upper-layer control gate part 50.

Metal or metallic silicide that can be patterned by an RIE (Reactive Ion Etching) method is used for the lower-layer control gate parts 40, and tungsten silicide (WSi), tungsten (W), or titanium nitride (TiN) is used, for example. Metallic silicide is used for the upper-layer control gate parts 50, and nickel silicide (NiSi) or cobalt silicide (CoSi) is used, for example.

The material of the lower-layer control gate parts 40 is selected by mainly taking both of processability and low resistance into consideration. Because the lower-layer control gate parts 40 are made of metallic silicide, the resistance is lower than that of polysilicon.

On the other hand, the material of the upper-layer control gate parts 50 is different from that of the lower-layer control gate parts 40 and is selected by mainly taking processability (patternability) into consideration. Therefore, it is preferable that metallic silicide obtained by siliciding a polysilicon film patterned by RIE is used as the material of the upper-layer control gate parts 50, for example.

As shown in FIG. 2B, the diffusion layer 60 is shared by a plurality of adjacent memory cells MC, and thus the memory cells MC are series-connected. The series-connected memory cells MC constitute a memory cell string CS.

The memory cell string CS is connected to a selective transistor STS or STD via a diffusion layer 61. The memory cell string CS is connected to a cell source CELSRC via the selective transistor STS on the source side, and is connected to the bit lines BL via the selective transistors STD on the drain side. An interlayer dielectric film ILD is filled between the gates (FG, CG) of adjacent memory cells MC and between a gate of the selective transistor ST and the gates (FG, CG) of the memory cells MC.

The selective gate lines SGD and SGS drive the selective transistors STD and STS. The driven selective transistors STD and STS become conductive, and the memory cell string CS is electrically connected between the bit line BL and the cell source CELSRC. With this operation, a voltage between the bit line BL and the cell source CELSRC can be applied to the memory cell string CS.

Thereafter, by driving the word line WL that is connected to an unselected memory cell MC in the memory cell string CS, the unselected memory cell MC is turned on. With this operation, a selected memory cell MC is connected between the bit line BL and the cell source CELSRC, and thus it becomes possible to selectively write data in the selected memory cell MC or to selectively read data from the selected memory cell MC.

The control gates CG of the memory according to the first embodiment each have a double-layer structure including the lower-layer control gate part 40 and the upper-layer control gate part 50. Therefore, the control gates CG can be formed while suppressing generation of voids therein. Furthermore, the control gates CG in the entirety are made of a material such as metallic silicide, metal, or a metallic compound, which has a resistance lower than that of silicon. Therefore, the control gates CG according to the first embodiment have a resistance lower than that of a gate made of polysilicon.

A manufacturing method of a memory according to the first embodiment is explained next.

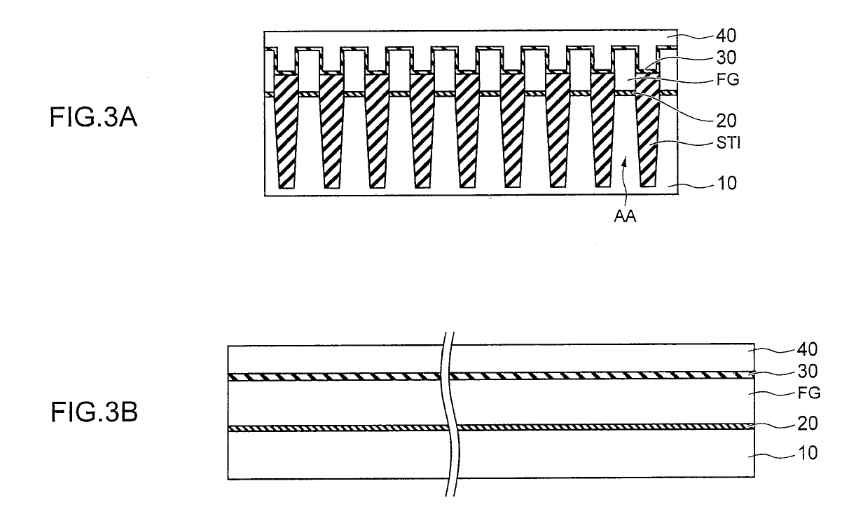

FIGS. 3A to 7B are cross-sectional views of the manufacturing method of a memory according to the first embodiment. FIGS. 3A, 4A, 5A, 6A and 7A correspond to the cross-section along the line A-A in FIG. 1, and FIGS. 3B, 4B, 5B, 6B and 7B correspond to the cross-section along the line B-B in FIG. 1.

First, the tunnel dielectric film 20 is formed on the semiconductor substrate 10 by a thermal oxidation process. Next, the material of the floating gates FG is deposited on the tunnel dielectric film 20 by a CVD (Chemical Vapor Deposition) method. The material of the floating gates is polysilicon, for example. A hardmask (not shown) is deposited on the material of the floating gates FG, and the hardmask is processed to be a pattern of the active areas AA by lithography. By using this hardmask as a mask, the material of the floating gates FG, the tunnel dielectric film 20, and a top portion of the semiconductor substrate 10 are anisotropically etched by RIE. With this process, trenches are formed at positions of the shallow trench isolations. Next, an insulating film (a silicon dioxide film, for example) is filled in the trenches and this insulating film is etched back, thereby forming the shallow trench isolations STI as shown in FIG. 3A. The top surface of the insulating film of the shallow trench isolations STI is located between the top surfaces and the bottom surfaces of the floating gates FG.

Next, the material of the gate dielectric film 30 is deposited on the material of the floating gates FG and the shallow trench isolations STI by a CDV method. The material of the gate dielectric film 30 can be an ONO (Oxide-Nitride-Oxide) film made of a silicon dioxide film, a silicon nitride film, and a silicon dioxide film, for example. Thereafter, the material of the lower-layer control gate parts 40 is deposited on the material of the gate dielectric film 30 by the CDV method. With this process, cross-sectional structures shown in FIGS. 3A and 3B are obtained.

As the material of the lower-layer control gate parts 40, a material that can suppress diffusion of metal more effectively as compared to silicon, has a lower resistance than that of silicon, and can be patterned by etching using the RIE method is used. That is, the material is tungsten silicide (WSi), tungsten (W), or titanium nitride (TiN), for example. The lower-layer control gate parts 40 are formed by depositing silicide (or metal), instead of being formed by silicidation of silicon. Accordingly, voids are hardly generated in the lower-layer control gate parts 40.

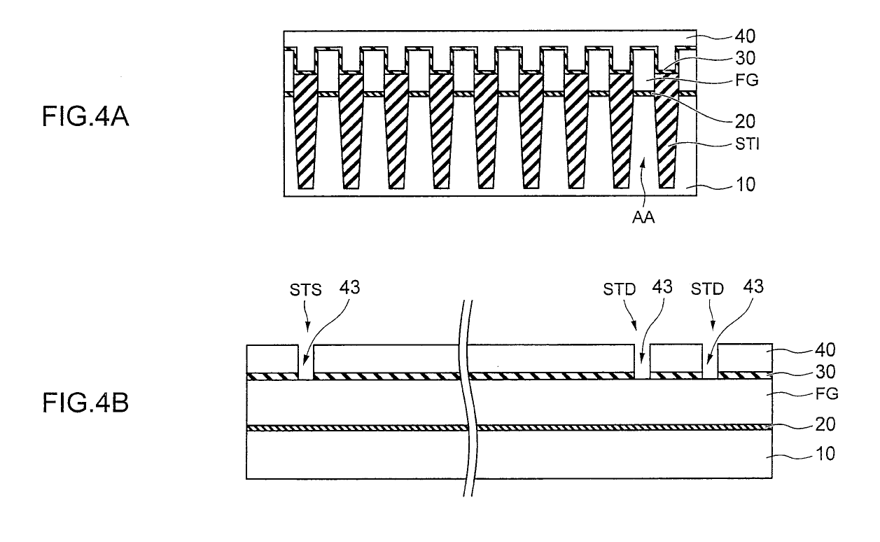

After depositing the material of the lower-layer control gate parts 40, the lower-layer control gate parts 40 and the gate dielectric film 30 in areas of the selective transistors STS and STD and in an area of a transistor of a peripheral circuit unit (not shown) are partially etched by lithography and RIE. With this process, an opening 43 is formed at gates of the selective transistors STS and STD and a gate of the transistor of the peripheral circuit unit (not shown). As a result, cross-sectional structures shown in FIGS. 4A and 4B are obtained.

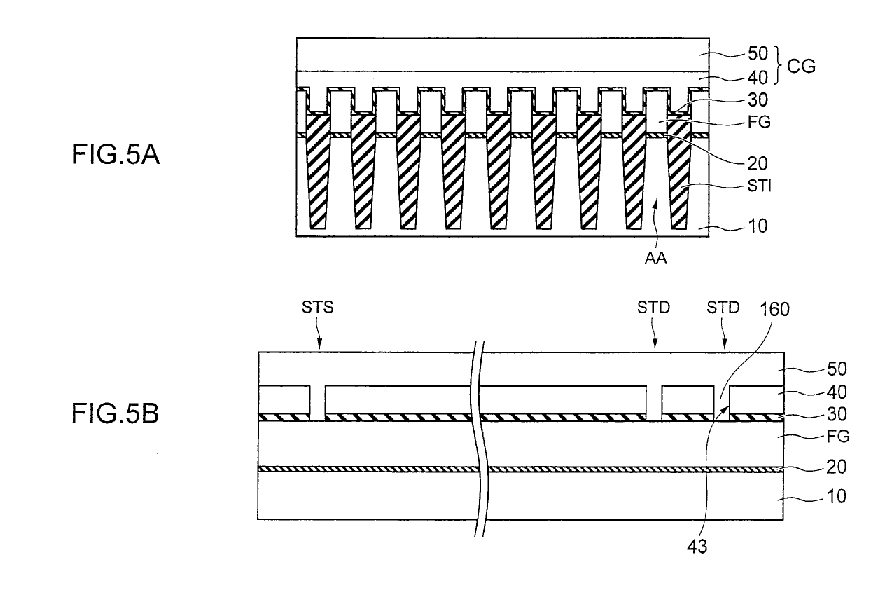

Furthermore, as shown in FIG. 5A, the material of the upper-layer control gate parts 50 is deposited on the material of the lower-layer control gate parts 40. In this case, the deposited material of the upper-layer control gate parts 50 is a material such as polysilicon, which is easily processed by the RIE method. The material of the upper-layer control gate parts 50 is also filled in the openings 43, thereby forming conducting parts 160 that make the floating gates FG and the control gates CG electrically conductive as shown in FIG. 5B. With this process, the upper-layer control gate parts 50 are connected to the floating gates FG in the selective transistors STS and STD and the transistor of the peripheral circuit unit. That is, in each of the selective transistors STS and STD and the transistor of the peripheral circuit unit, the floating gate FG and the control gate CG function as a single gate.

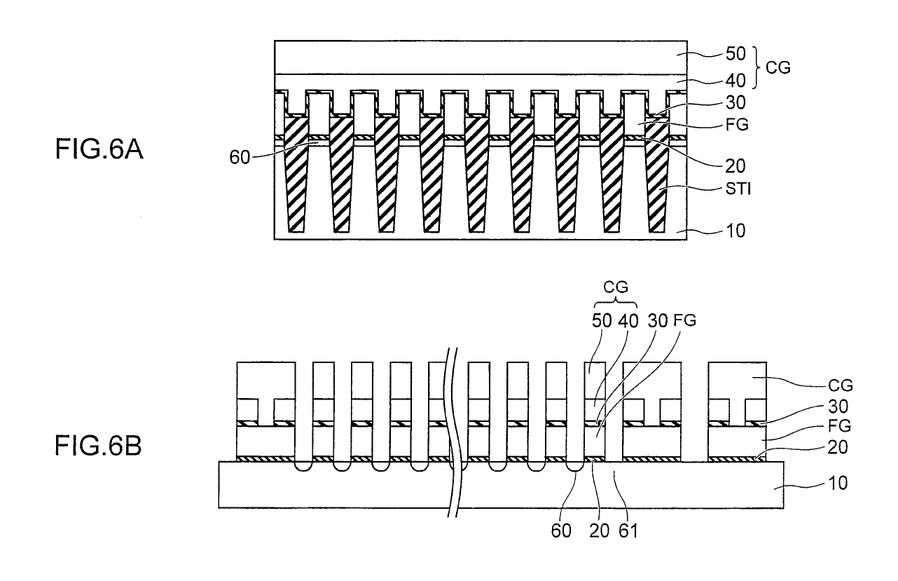

Next, as shown in FIG. 6B, gates of the memory cells MC are processed by lithography and RIE. More specifically, by using a hardmask that has been processed in a pattern of the control gates CG by lithography or the like, the material of the upper-layer control gate parts 50, the material of the lower-layer control gate parts 40, the gate dielectric film 30, and the material of the floating gates FG are sequentially etched by RIE. With this process, the floating gates FG, the gate dielectric films 30, the lower-layer control gate parts 40, and the upper-layer control gate parts 50 are formed.

Next, as shown in FIGS. 6A and 6B, an impurity is implanted into the semiconductor substrate 10 between the memory cells MC in order to form the diffusion layers 60 and 61.

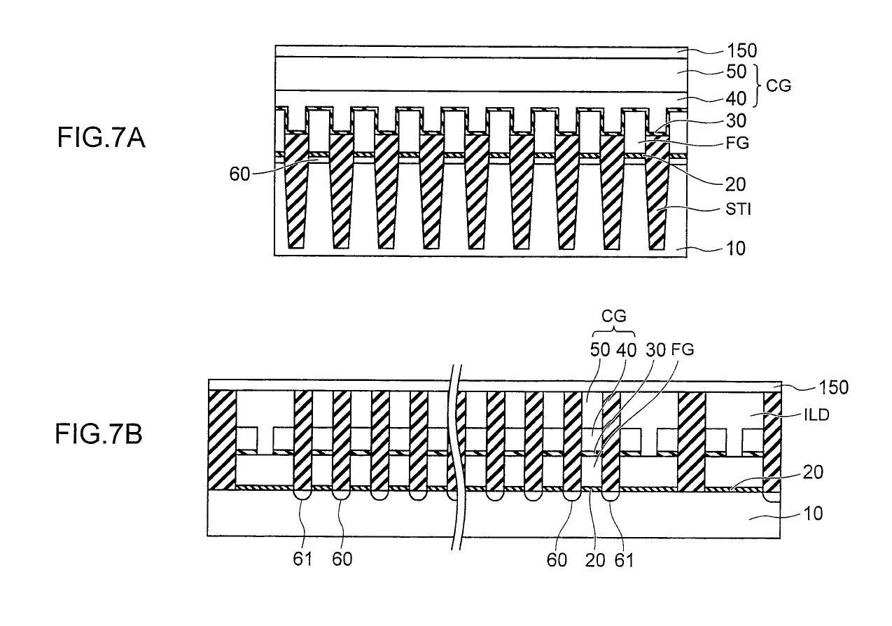

Next, as shown in FIG. 7B, the interlayer dielectric film ILD is deposited on the diffusion layers 60 and 61, the memory cells MC, the selective transistors STS and STD, and the transistor of the peripheral circuit unit. The interlayer dielectric film ILD can be a silicon dioxide film or a silicon nitride film, for example.

Next, the interlayer dielectric film ILD is polished by a CMP (Chemical Mechanical Polishing) method and etched by the RIE method until the top surfaces of the control gates CG are exposed. Furthermore, a metallic film 150 for silicidation is deposited on the control gates CG and the interlayer dielectric film ILD by sputtering or the like. With this process, cross-sectional structures shown in FIGS. 7A and 7B are obtained.

The material of the metallic film 150 is preferably a material having a resistance as low as possible as it is silicided. At this stage, the upper-layer control gate parts 50 of polysilicon have been already patterned. Therefore, the upper-layer control gate parts 50 do not need to be patterned after silicidation, and thus the metallic film 150 can be selected regardless of the processability of the upper-layer control gate parts 50. That is, it suffices that the material of the metallic film 150 is a material with a lower resistance that can satisfy the specifications of the wiring resistance.

Next, heat treatment is performed to silicide the upper-layer control gate parts 50 by the metallic film 150. Silicide, metal, or a metallic compound, such as tungsten silicide (WSi), tungsten (W), or titanium nitride (TiN), is used here as the material of the lower-layer control gate parts 40. Therefore, when the upper-layer control gate parts 50 are silicided, the lower-layer control gate parts 40 can suppress diffusion of metal more effectively as compared to a case of using silicon, which has a higher reactivity with metal.

The upper-layer control gate parts 50 are formed directly on the lower-layer control gate parts 40 by substantially entirely siliciding the upper-layer control gate parts 50 using a polysilicon layer.

Thereafter, an interlayer dielectric film is deposited on the control gates CG, and contacts, wirings, and the like are formed by a known method, thereby completing the memory according to the first embodiment.

In the first embodiment, while the upper-layer control gate parts 50 are formed by siliciding polysilicon, the lower-layer control gate parts 40 are formed by depositing silicide, metal, or a metallic compound. That is, because the lower-layer control gate parts 40 are deposited having metal already contained therein, voids are hardly generated in the control gates CG even when the upper-layer control gate parts 50 are fully silicided.

For example, as shown in FIG. 7A, when the control gates CG are embedded between adjacent floating gates FG in the row direction, voids are easily generated in the control gates CG between the adjacent floating gates FG if the control gates CG are fully silicided. However, in the first embodiment, because the lower-layer control gate parts 40 are embedded in advance between the adjacent floating gates FG, voids are hardly generated in the control gates CG between the adjacent floating gates FG.

In the siliciding process, there is a possibility that metal of the metallic film 150 is diffused into the lower-layer control gate parts 40. However, in the lower-layer control gate parts 40, the amount of silicon that reacts to silicide is smaller than that of a silicon layer. Because of this, in the first embodiment, the amount of metal required for silicidation can be smaller than that of a case where control gates are entirely formed by a silicon layer and then the silicon layer is fully silicided. Therefore, even when metal is diffused into the lower-layer control gate parts 40, generation of voids in the control gates CG can be suppressed.

By suppressing generation of voids in the control gates CG in this manner, it is possible to maintain high capacitive coupling between the floating gate FG and the control gate CG in each of the memory cells MC. This can improve the reliability in data writing and data reading.

The upper-layer control gate parts 50 are formed directly on the lower-layer control gate parts 40 by substantially entirely siliciding the upper-layer control gate parts 50 constituted by a polysilicon layer. Accordingly, the resistance value of the control gates CG can be reduced.

Furthermore, because the upper-layer control gate parts 50 are silicided after being patterned, it suffices that a material having a resistance as low as possible is selected as the material thereof regardless of the processability. Accordingly, the resistance value of the entire control gates CG can be reduced.

As can be understood from the above explanations, the first embodiment can form the control gates CG with a lower resistance and suppress generation of voids at the same time.

### Second Embodiment

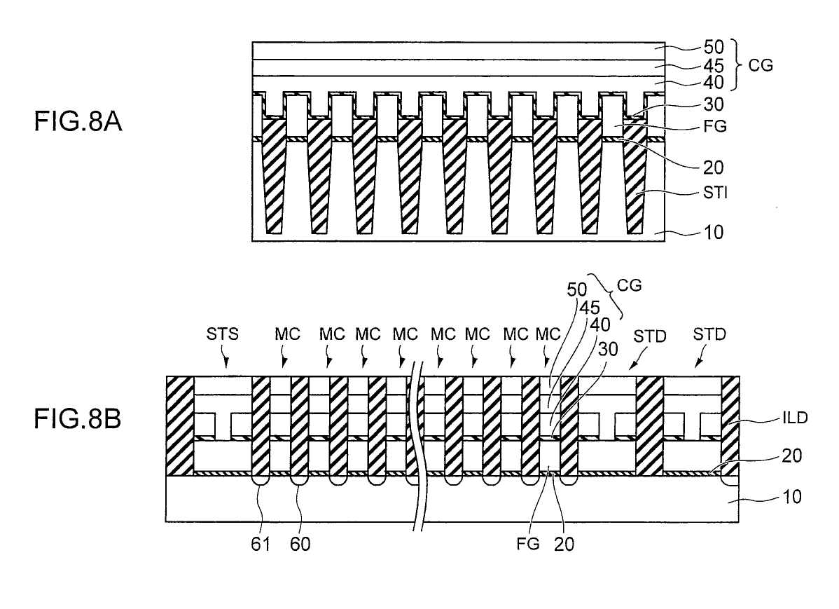

FIGS. 8A and 8B are cross-sectional views showing a configuration of a semiconductor storage device according to a second embodiment. The semiconductor storage device according to the second embodiment includes, in each of the control gate CG, an intermediate control gate part 45 between the lower-layer control gate part 40 and the upper-layer control gate part 50. The intermediate control gate part 45 uses polysilicon and is not silicided. That is, the control gates CG according to the second embodiment each have a triple-layer structure. Other configurations of the second embodiment can be identical to those of the first embodiment.

Furthermore, in a manufacturing method of a memory according to the second embodiment, it suffices in the siliciding process explained with reference to FIGS. 7A and 7B that the silicidation of the upper-layer control gate parts 50 is stopped in the middle of the process and the top portions thereof are silicided. Other processes of the second embodiment can be identical to the corresponding processes of the first embodiment.

At the gates of the selective transistors ST and the gate of a transistor of a peripheral circuit unit, the control gates CG are conductive to the floating gates FG via the conducting parts 160, and the control gates CG and the floating gates FG integrally constitute a gate, respectively. Therefore, when the upper-layer control gate parts 50 are fully silicided, the metal of the metallic layer 150 occasionally reaches to the floating gates FG of the selective transistors ST and the transistor of the peripheral circuit unit via the conducting parts 160. The control gates CG are made of metallic silicide or metal, and the floating gates FG are formed by polysilicon. Therefore, because the silicon of the floating gates FG is used for silicidation, there is a possibility that voids are generated in the floating gates FG.

When such a problem occurs, the upper-layer control gate parts 50 are not fully silicided and only the top portions thereof are silicided as described in the second embodiment. With this process, generation of voids at the gates of the selective transistor ST and the gate of the transistor of the peripheral circuit unit can be prevented. Furthermore, it is also possible to prevent a state such that the silicidation reaches to the gate dielectric film and thus a threshold voltage is fluctuated. In addition, it is possible to prevent a state such that the resistances in the entire conducting parts 160 are varied in a case where the silicidation is varied and thus some of the conducting parts 160 are silicided while the remaining conducting parts 160 are not silicided. In this manner, the second embodiment contributes to suppressing the variations in the resistance value of a resistive element in a peripheral part.

The first and second embodiments can be applied not only to a NAND flash memory but also to other semiconductor storage devices such as a NOR flash memory.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a memory cell comprising a charge accumulate layer above a semiconductor substrate and a control gate above the charge accumulate layer, the charge accumulate layer being capable of accumulating charges therein, the control gate being configured to control an amount of the charges accumulated in the charge accumulate layer, wherein
the control gate comprises:
a lower-layer control gate part formed by metal or metallic silicide which is processable by etching; and
an upper-layer control gate part formed by a material different from that of the lower-layer control gate part.

2. The device of claim 1, wherein
the lower-layer control gate part is formed by using tungsten silicide, tungsten, or titanium nitride, and
the upper-layer control gate part is formed by using nickel silicide or cobalt silicide.

3. The device of claim 1, wherein the control gate further comprises an intermediate control gate part formed by using silicon between the lower-layer control gate part and the upper-layer control gate part.

4. The device of claim 2, wherein the control gate further comprises an intermediate control gate part formed by using silicon between the lower-layer control gate part and the upper-layer control gate part.

5. A manufacturing method of a semiconductor device comprising:
forming a charge accumulate layer arranged above a semiconductor substrate, the charge accumulate layer capable of accumulating charges therein
depositing a lower-layer control gate material above the charge accumulate layer, the lower-layer control gate material being formed by using metal or metallic silicide which is processable by etching,
depositing a polysilicon layer on the lower-layer control gate material,
forming a lower-layer control gate part by processing the lower-layer control gate material and the polysilicon layer in a pattern of a control gate, the control gate configured to control an amount of the charges accumulated in the charge accumulate layer, and
forming an upper-layer control gate part by siliciding the polysilicon layer.

6. The method of claim 5, wherein
the lower-layer control gate part is formed by using tungsten silicide, tungsten, or titanium nitride, and
the upper-layer control gate part is formed by using nickel silicide or cobalt silicide.

7. The method of claim 5, wherein the upper-layer control gate part is formed directly on the lower-layer control gate part by substantially fully siliciding the polysilicon layer.

8. The method of claim 6, wherein the upper-layer control gate part is formed directly on the lower-layer control gate part by substantially fully siliciding the polysilicon layer.

9. The method of claim 5, wherein an intermediate control gate part made of polysilicon is formed between the upper-layer control gate part and the lower-layer control gate part by siliciding only a top portion of the polysilicon layer.

10. The method of claim 6, wherein an intermediate control gate part made of polysilicon is formed between the upper-layer control gate part and the lower-layer control gate part by siliciding only a top portion of the polysilicon layer.
